(19) United States
(12) Patent Application Publication
(10) Pub. No.: US 2007/0044916 A1
(43) Pub. Date: Mar. 1, 2007

(54) Vacuum processing system

(76) Inventors: Masakazu Isozaki, Kudamatsu (JP); Seiichiro Kanno, Kodaira (JP); Hideki Kihara, Kudamatsu (JP); Hiroho Kitada, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/214,951

(22) Filed: Aug. 31, 2005

(51) Int. Cl. C23F 1/00; C23C 16/00

(52) U.S. Cl. 156/345.52; 118/725

(57) ABSTRACT

A ceramic film is formed by a spray method on a base material of an electrostatic attraction device. Electrode films for electrostatic attraction are formed by a spray method on a surface of the ceramic film. A ringular heater film is formed in a spray method between the electrode films in a radial direction of the electrode films. In addition, a ceramic film is formed by a spray method on upper surfaces of the electrode films and the heater film.

### FIELD OF THE INVENTION

The present invention relates to a system for processing samples supplied as substrate-like processing objects, such as semiconductor wafers in the vacuum state. More particularly, the present invention relates to a vacuum processing system that performs continuous processing of samples in a vacuum vessel or chamber by using plasma.

### BACKGROUND OF THE INVENTION

In recent years, with demands for enhanced accuracy and density of semiconductor devices, processing with enhanced fineness and accuracy is required for a circuit pattern that is formed on a semiconductor wafer. Anisotropy should be realized to obtain fine and high accuracy processing.

For example, according to a general practice, when performing etching a wafer by using plasma (plasma etching), the bias voltage is applied to the wafer, and ions are accelerated by the electric field to be drawn along the vertical direction, whereby the anisotropy is realized. In this event, the wafer has heat input occurring by the bias voltage being applied, so that the wafer temperature increases.

A close relationship exists between the wafer temperature and the deposition efficiency of reaction products being deposited on sidewalls during etching. The linewidth (CD (critical dimension)) of the circuit pattern of a finally obtainable wafer is significantly influenced by reaction products deposited on sidewalls during etching. Consequently, unless appropriate control of the wafer temperature can be performed, there occurs a nonuniform processed profile not having reproducibility. The distribution of reaction products has a tendency that the density thereof is lower than that in the vicinity of the center of the wafer. As such, in order to obtain a uniform processed profile in the plane of the wafer, positive control should be performed for the temperature distribution of the wafer. In addition, the density distribution of the reaction products in the wafer is variant with a variation in etching conditions. As such, in a case where the etching conditions vary during a process as in the case that an anti-reflective coating and polysilicon are continuously processed, the temperature distribution should be shifted to an optimal temperature distribution in coordination with conditions.

However, according to general conventional methods, in order to control an average temperature distribution of a wafer, the temperature of an electrostatic attraction device, which is used as a wafer stage, is regulated to a constant temperature by using a coolant discharged from a circulator. In this case, a heat transfer gas, such as helium, is supplied to a portion between the wafer and the electrostatic attraction device to secure heat transfer characteristics. These methods are advantageous in that since the heat capacity of coolant is large, even when the amount of heat gain from the plasma is large, the wafer temperature does not sharply increase and hence the temperature is relatively stable. However, the methods are not suitable for varying the wafer temperature with good response characteristics in coordination with conditions as described above.

For example, methods have been proposed that reduces a CD shift amount by controlling the increase of the wafer temperature while a plurality of wafers are being continuously processed. According to an example of such methods, the flow rate of coolant being circulated inside an electrode on which wafers are stacked is regulated in unit of the wafer (see Japanese Patent Laid-Open No. 2003-203905, for example).

According to the conventional technique described above, it is not considered that the temperature distribution in the plane of the wafer should be appropriately regulated. As such, problems remain pending resolution, particularly, in a case where etching conditions vary in such an event where an anti-reflective coating and polysilicon are continuously processed during a single process. That is, problems occur in such a case where an optimal temperature distribution in the plane of the wafer should be realized.

More particularly, sufficient consideration is not taken into a configuration necessary to quickly shift the temperature distribution in the plane of the wafer to an appropriate one in coordination with an appropriate etching condition(s) with respect to a respective film layer. Further, sufficient consideration is not taken regarding a configuration for being formed by accurately and appropriately shifting the temperature distribution, consequently leading to a loss of the efficiency for wafer processing.

### SUMMARY OF THE INVENTION

Objects of the present invention are, but not limited to, as follows:

(1) First object of the invention is to provide an electrostatic attraction device at a low cost, wherein a temperature distribution in a plane of the electrostatic attraction device can be shifted with good response characteristics in coordination with a respective etching condition, thereby to enable a uniform bias voltage can be applied to an wafer;

(2) Second object of the invention is to provide an electrostatic attraction device, wherein a temperature distribution in a plane of the electrostatic attraction device can be finely regulated in coordination with a respective etching condition; and

(3) Third object is to provide an electrostatic attraction device wherein power consumption of heating systems can be restrained, and a thermal load imposed on a circulator discharging coolant to the electrostatic attraction device can be reduced.

The first object is achieved by a structure formed in the manner that a ceramic film is formed by a spray method on a base material of the electrostatic attraction device. Electrode films for electrostatic attraction are formed by a spray method on a surface of the ceramic film, a ringular heater film is formed in a spray method between the electrode films in a radial direction of the electrode films, and a ceramic film is formed by a spray method on upper surfaces of the electrode films and the heater film.

The second object is achieved by a structure wherein a plurality of heater films are each provided in an inner portion and an outer portion in the radial direction on the electrostatic attraction device.

The third object is achieved by a structure wherein a vacuum insulation layer is formed in a base material of the electrostatic attraction device, and heater films are provided in an inner portion and an outer portion in the radial direction of the vacuum insulation layer.

According to the present invention, the electrostatic attraction device containing the heater(s) buried therein in a spray method can be provided, so that manufacturing costs can be reduced in comparison to the case of a sintered ceramics. Further, according to the present invention, a temperature distribution in a plane of a wafer can be controlled with good response characteristics by control of the heater(s) buried in the vicinity of the wafer. Further, the temperature distribution in the plane of the wafer can be varied in coordination with a respective etching condition. Furthermore, according to the present invention, power consumption of the heater(s) can be restrained, thereby enabling a thermal load on a circulator to be reduced.

### BRIEF DESCRIPTION OF THE DRAWINGS

The above-mentioned and other objects, features, and advantages of this invention will become more apparent by reference to the following detailed description of the invention taken in conjunction with accompanying drawings, wherein:

FIG. 1 is a detailed cross section view of an electrostatic attraction device according to a first embodiment of the present invention;

FIGS. 2A and 2B are views showing an overall configuration of a sample table for being used in the embodiment shown in FIG. 1, wherein FIG. 2A is a cross sectional view taken along a line A-A of FIG. 2B, and FIG. 2B is an elevational cross sectional view showing the sample table and a related control system;

FIG. 3 is an enlarged view of a power supply section of a heating system of the electrostatic attraction device;

FIG. 4 is a diagram showing a CD shift amount in a plane of a wafer after etching performed with a heating system not operated, according to the conventional technique;

FIG. 5 is a diagram showing a CD shift amount in a plane of a wafer after etching performed with a heating system operated, according to the invention;

FIGS. 6A to 6C are comparative diagrams showing CD shift amounts under respective etching conditions, according to the conventional technique and the invention;

FIGS. 7A and 7B are views showing an overall configuration of a sample table for being used in a second embodiment shown in FIG. 1, wherein FIG. 7A is a cross sectional view taken along a line A-A of FIG. 7B, and FIG. 7B is an elevational cross sectional view showing a sample table and a related control system;

FIGS. 8A to 8D are diagrams showing effects of the second embodiment, wherein FIG. 8A shows a temperature distribution in a plane of a wafer with a single heating system, FIG. 8B shows a temperature distribution in a plane of a wafer with double heating systems, and FIGS. 8C and 8D each showing a temperature distribution in a plane of a wafer with double heating systems and a vacuum insulation (thermal insulation) layer; and

FIG. 9 is a flow diagram showing flow of operation of a process of a wafer that is executed by a vacuum processing system according to the first embodiment shown in FIG. 1 or the second embodiment shown in FIG. 7.

### DETAILED DESCRIPTION OF THE PREFERRED EMBODIMENTS

### First Embodiment

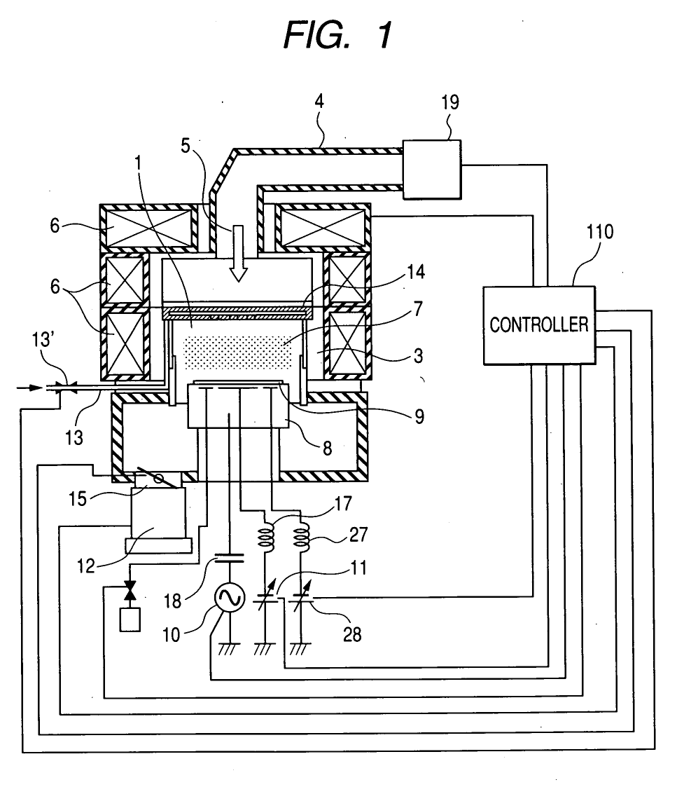

FIGS. 1 to 3 shows a first embodiment of the present invention by way of an example wherein the embodiment is adapted in an effective magnetic field microwave plasma processor.

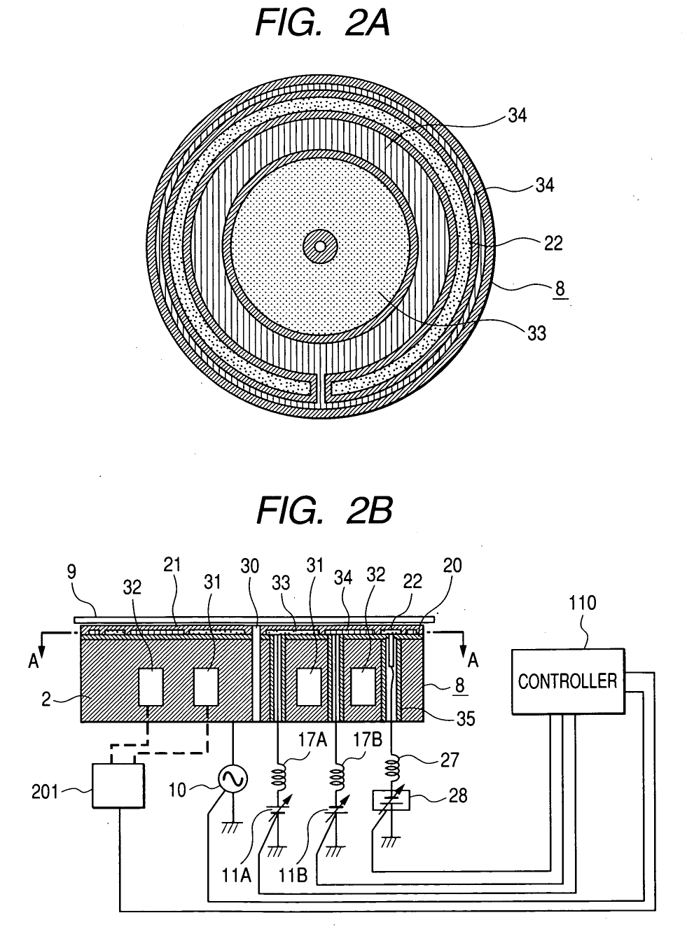

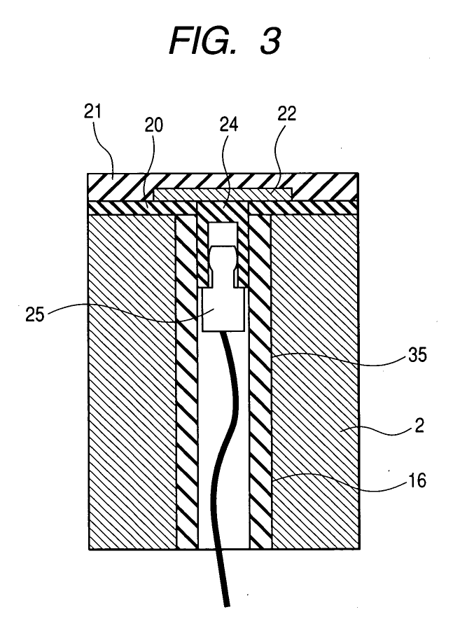

FIG. 1 is an overall system configuration view inclusive of an essential portion elevational cross sectional view of the configuration of a vacuum processing system according to the first embodiment of the invention. FIGS. 2A and 2B are views showing an overall configuration of a sample table for being used in the embodiment shown in FIG. 1. FIG. 2A is a cross sectional view taken along a line A-A of FIG. 2B, and FIG. 2B is an elevational cross sectional view showing the sample table and a related control system. FIG. 3 is an enlarged view of a power supply section of a heating system of the sample table shown in FIGS. 2A and 2B.

To begin with, the configuration of the first embodiment will be described by reference to FIG. 1. In the vacuum processing system according to the present embodiment, a quartz window 14 is disposed above a vacuum chamber unit 3, and a wafer 9 is held in a vacuum processing chamber 1 by using an electrostatic attraction device 8. While an electrostatic attraction device according to the present invention is adapted for the electrostatic attraction device 8, it will be described in detail further below.

First, processing gases are introduced into a vacuum processing chamber 1 through a processing gas introduction pipe 13. The processing gases are converted into plasma 7 by interaction between a microwave 5 and a magnetic field. The microwave 5 is generated by a microwave oscillator 19 and is introduced through a waveguide 4, and the magnetic field is generated by the coil 6 wound around a vacuum chamber unit 3. The process (etching process in the present case) is performed in the manner that the wafer 9 is exposed to the plasma. Particularly, a high frequency power source 10 connected through a capacitor 18 controls incidence of ions to thereby control the etching state. DC power sources 11 each apply voltage to the electrostatic attraction device 8. In the drawing, numeral 17 denotes a coil that prevents entrance of high frequency components. Numeral 12 denotes a vacuum pump 12. The pressure in the processing chamber is maintained constant by adjustment of the opening of a valve 15. A heater power source 28 is connected to a heater film in the electrostatic attraction device 8 through a coil 27.

The high frequency power source 10, the DC power sources 11, the vacuum pump 12, the coil 6, a microwave oscillator 19, and a shut-off valve 13′ provided to a processing gas supplying pipe 13 are connected to a controller unit 110. The heater power source 28 is also connected with the controller unit 110. Thereby, the connected devices are monitored by the controller unit 110 for their operation states and their signals are received thereby, and instructions for their operation are issued to the devices. That is, the controller unit 110 regulates operations of respective portions of vacuum processing system according to the present embodiment.

The electrostatic attraction device 8 being used in the embodiment will be described in details with reference to FIGS. 2A, 2B and 3.

The electrostatic attraction device 8 is a sample table that allows the wafer 9, which is a sample representing a processing object, to be mounted and held on its upper surface. The material of a base material 2, which is an essential component of the electrostatic attraction device 8, is a metal having electro-conductivity. In a base material 2, there are provided coolant channels 31 and 32, insides of which allows flowing of coolants serving as heat exchange mediums, in a center side portion and outer periphery side portion, respectively, of the base material 2. The coolants having the temperatures different from one another circulate the insides of the respective coolant channels 31 and 32. Thereby, temperature of the base material 2 or the electrostatic attraction device 8 (sample table) is regulated to be appropriate in the center side and outer periphery side thereof.

The respective coolants circulated through the coolant channels 31 and 32 travel through a coolant temperature regulator 201, whereby the coolants are regulated to predetermined temperatures and then recirculated to return to coolant channels 31 and 32. Similarly as for example, the high frequency power source 10, electrostatic-attraction dedicated DC power sources 11A and 11B, a heater power source 28, also the coolant temperature regulator 201 is connected with the controller unit 110. Thereby, the operation of the coolant temperature regulator 201 is monitored and regulated in accordance with instructions received.

In the vacuum processing chamber unit 3 of the vacuum processing system thus configured, the density of reaction products formed corresponding to processing is different in the near-center portion and near-outer periphery portion of the wafer 9. More specifically, in the present embodiment, cases can take place where the density in near-outer periphery portion tends to become relatively low. As such, when the temperature distribution in the plane of the wafer 9 is homogenized, the CD (critical dimension) in a near-outer periphery portion tends to be reduced. To overcome this problem, in the present embodiment, the temperature of coolant in the coolant channel 32 on the outer periphery side is set lower than the coolant temperatures of the coolant channel 31 on the inner periphery side.

On the surface of the base material 2, a high resistance alumina film 20 for proving electrical insulation is disposed by being splayed. On the surface of the high resistance alumina film 20, electrostatic attraction electrode films 33 and 34 of an electro-conductive material, such as tungsten or nickel, are disposed by being sprayed with an appropriate mask to predetermined shapes.

A heater film 22 of an electro-conductive material, such as tungsten or nickel, is sprayed between the electrostatic attraction electrode films 34 along the radial direction thereof. The electrostatic attraction films 34 each have a substantially ringular shape, and the electrostatic attraction film 33 on the center side has a substantially circular shape. The heater film 22, which is provided on the inner side of electrostatic attraction film 34 on the outer periphery side with respect to the radial direction of the electrostatic attraction device 8, has a substantially ringular shape. An inner periphery side and outer periphery side of the heater film 22 are sandwiched by the electrostatic attraction films 34.

Further, a high resistance ceramic film 21 to be used as an electrostatic attraction film is disposed by being sprayed in such a manner as to cover the surfaces of the base material 2, the high resistance alumina film 20, the heater film 22, and the electrostatic attraction electrode films 33 and 34. A wafer mounting surface on which the wafer 9 is to be mounted is formed on the high resistance ceramic film 21. In the state where the wafer 9 is placed on the high resistance ceramic film 21, power is supplied to the electrostatic attraction films 33 and 34, and electrostatic attraction forces with static electricity are generated by static in the high resistance ceramic film 21 sandwiched by the wafer 9 and the underlying film layer. Thereby, the wafer 9 is held.

The heater film 22 is thus provided on the inner side between the electrostatic attraction electrode films 34 in such a manner as to be surrounded thereby. As such, an outer peripheral portion of the wafer 9 is compressed by attraction forces caused by the electrostatic attraction electrode films 34 along the direction of the electrostatic attraction device 8, whereby leak of helium gases can be restrained. Further, response characteristics with respect to temperature variations can be improved since the heater film 22 is disposed closer to the wafer 9.

In the electrostatic attraction according to the present embodiment, the signs different from one another are imparted to the respective electrostatic attraction electrode films 33 and 34. Thereby, electric charges of the different signs are induced to the electrostatic attraction film, whereby electrostatic attraction forces are generated to effect the attraction. Thereby, the wafer 9 can be cooled in coordination with the temperature distribution formed in the base material 2.

However, since the pressure in the processing chamber is reduced to a level of several Pa's, heat transfer is insufficient as in that state. To overcome this problem, a through-hole 30 is provided in the base material 2 to introduce a heat transfer gas, such as helium gas, whereby the heat transfer between the wafer and the electrostatic attraction film is secured. Although not described in detail in the present embodiment, the through-hole 30 is provided so that pressure loss of the heat transfer gas is minimized and the gas is transferred to the entirety of the reverse side of the wafer 9, whereby a groove pattern is formed on the surface of the electrostatic attraction film.

In addition, for power supply to the electrostatic attraction films 33 and 34, the electrostatic attraction films 33 and 34 are, respectively, connected to coils 17A and 17B and further to the DC power sources 11A and 11B via conductive materials passed through insides of holes formed in the base material 2 and the high resistance alumina film 20. Similarly, the heater film 22 is connected to a coil 27 and the heater power source 28 via a conductive material passed through the inside of a hole formed in the base material 2 and the high resistance alumina film 20, whereby power is supplied to the heater film 22.

As shown in FIG. 3, the power supply to the heater is performed through a through-hole 16 formed in the base material and the high resistance alumina film 20. In the present embodiment, a through-hole 16 is provided in the base material 2. A ceramic pipe 35 for providing electrical insulation is buried in the through-hole 16, and a socket 24 of an electro-conductive material, such as titanium, is buried in the end of the ceramic pipe 35. The socket 24 is placed to create electrical conduction to the heater film 22, and the heater film 22 is sprayed thereover. When the socket 24 is coupled with a plug 25 connected to the AC or DC heater power source 28 via a cable, the heater can be supplied with power. The coil 27 serves as a filter that prevents high frequency voltage to flow into the heater power source 28. Further, the base material 2 is connected with the high frequency power source 10 that is provided to perform anisotropic etching by applying a bias voltage to the wafer 9 to thereby draw-in ions in plasma.

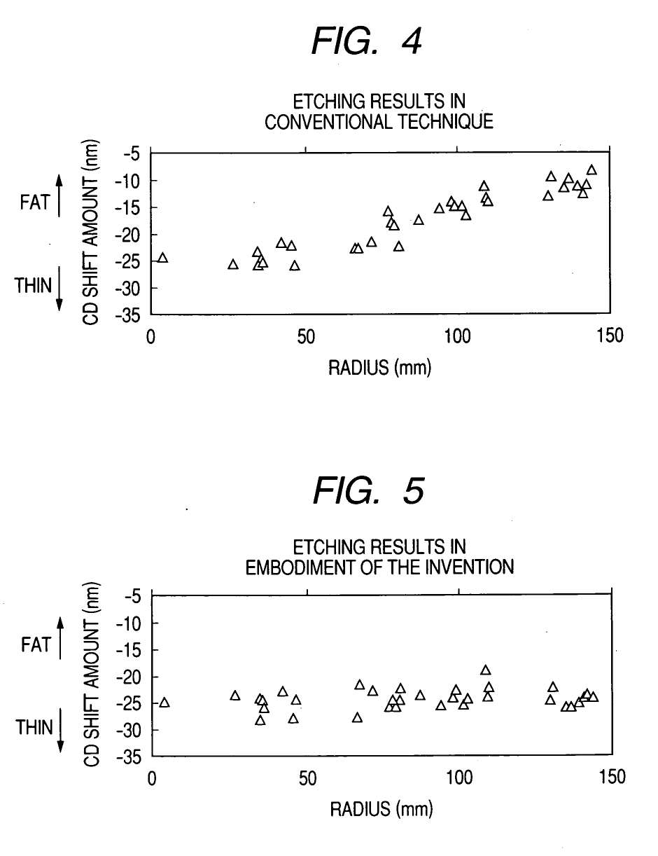

As a comparative example for the use of describing effects of the present embodiment, FIG. 4 shows a CD shift amount in the plane of the wafer when the etching was performed without the heater being operated. From the figure, it can be known that the CD shift amount on the outer periphery of the wafer is relatively small, that is, the CD is enlarged in comparison to the near-center portion.

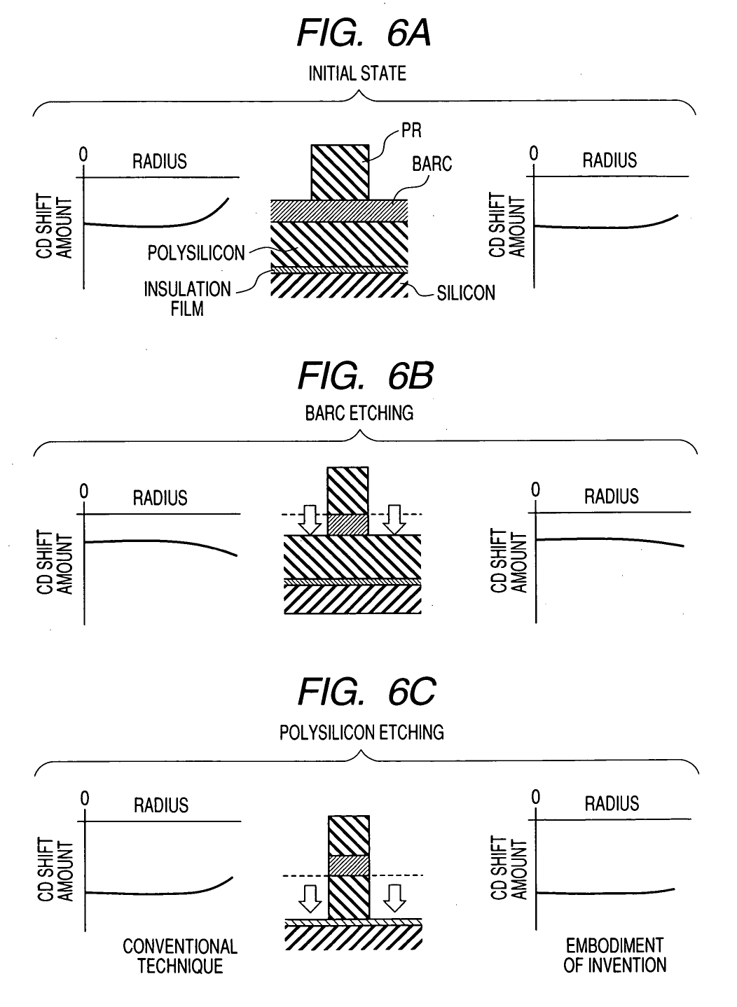

FIG. 5 shows a CD shift amount in the plane of the wafer in the event that etching was performed with the heater according to the present embodiment being operated to thereby increase the temperature of the outer periphery. From the figure, it can be known that the increase in the temperature of a near-outer periphery portion causes the reduction in the deposition efficiency of reaction products in the outer peripheral portion of the wafer, and consequently, the CD is reduced, and the CD shift amount is homogenized in the plane of the wafer.

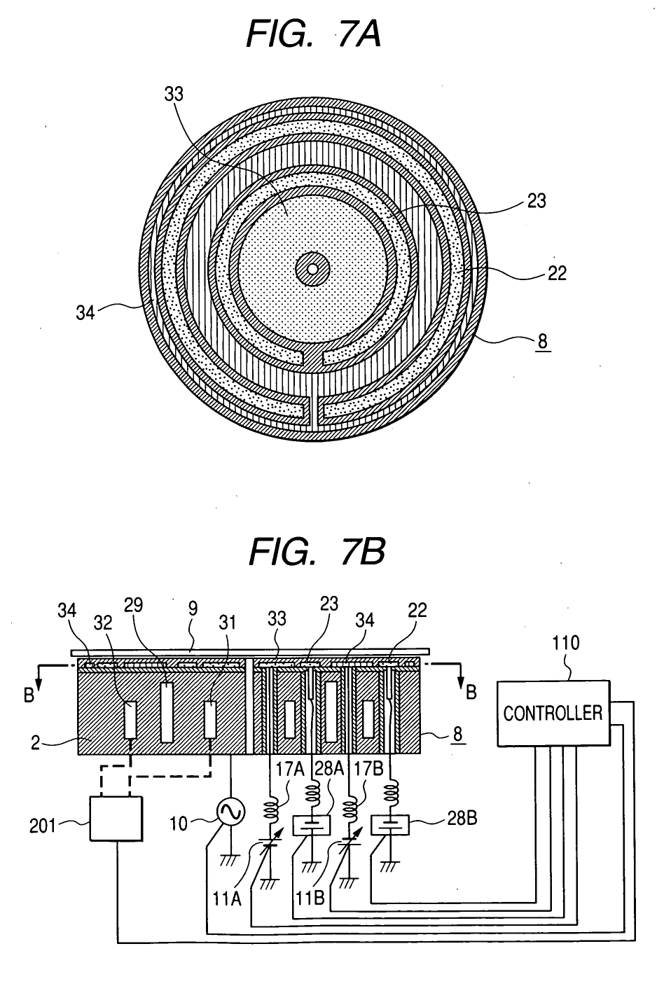

FIGS. 6A to 6C show the results of etching performed with the heater being not operated in coordination with the respective condition and the results of etching performed with being operated in coordination with the respective condition. In conjunction with the present embodiment, a relevant description will be provided with reference to a case where different films of a bottom antireflective coating (“BARC”) and a polysilicon film (“polysilicon”) are continuously processed by using a resist mask (“PR”).

Generally, films such as those are etched in the following manner. A BARC is etched by using a gas mixture of chlorine and oxygen, and a polysilicon film is etched by using a gas mixture of chlorine, oxygen, and oxygen bromide. The drawings are each a schematic view showing the film structure in the center. The lefthand portion of the view shows a CD shift amount in a case where etching according to the conventional technique was performed without the heater being not operated. The righthand portion of the view shows a CD shift amount in a case where etching according to the present embodiment was performed. FIG. 6A shows an initial state prior to the start of the process, and FIG. 6B is illustrative of the etching process of a BARC. FIG. 6C is illustrative of the etching process of a polysilicon film formed below the BARC.

It can be known that, as shown in FIG. 6B, according to the conventional technique, in the case of the process of the BARC film, the CD shift (variation) amount in the near-periphery portion of the wafer is relatively small in comparison to that in the near-center portion of the wafer. That is, the shape of the film is relatively fat or thick. In contrast to the BARC, as shown in FIG. 6C, in the case of the process of the polysilicon film, the CD shift amount in the near-periphery portion of the wafer is relatively larger. That is, the shape of the film after the process is relatively thin.

From these shown results, it was verified that the total of the CD shift amounts after etching of the BARC and the polysilicon is relatively small in the near-outer periphery portion, that is, the CD in the near-outer periphery portion is large.

Then, according to the present embodiment, as shown in FIG. 6B, in the case of etching of the BARC, 50 W of power was supplied to the heater buried in the outer periphery, and the temperature of the outer periphery was increased. As a result, it was verified that in the present embodiment, the deposition efficiency of reaction products in the near-outer periphery portion decreases, and the CD shift amount in the outer periphery decreases. It can further be known that, as shown in FIG. 6C, in etching of the polysilicon, the power for supply to the heater was restrained to 10 W to thereby reduce the temperature in the near-outer periphery portion, whereby the in-plane CD distribution finally obtained was homogenized.

Thus, according to the present embodiment, all the components constituting the electrostatic attraction device, i.e., the base material, the heater, the insulation material between the electrostatic attraction electrodes, the heater, the electrostatic attraction electrodes, and the electrostatic attraction film, are manufactured by the low-cost spraying technique. Consequently, the low cost heater-containing electrostatic attraction device can be provided. In addition, the heater film is disposed between the electrostatic attraction electrodes along the radial direction thereof. Consequently, the heating system can be provided in the vicinity of the wafer, so that the in-plane temperature distribution can be expected to vary with good response characteristics. The bias voltage in the plane of the wafer can be expected to be homogenized by thinning of the sprayed film between the base material and the wafer and by homogenizing the impedance.

Further, when the power for the heater buried in the outer periphery of the wafer is regulated in association with alteration of the etching conditions during the process, the density distribution, the deposition efficiency, and the like of reaction products under the respective etching condition can be controlled. Consequently, the electrostatic attraction device that obtains homogenized CD distribution in the plane of the wafer can be provided.

### Second Embodiment

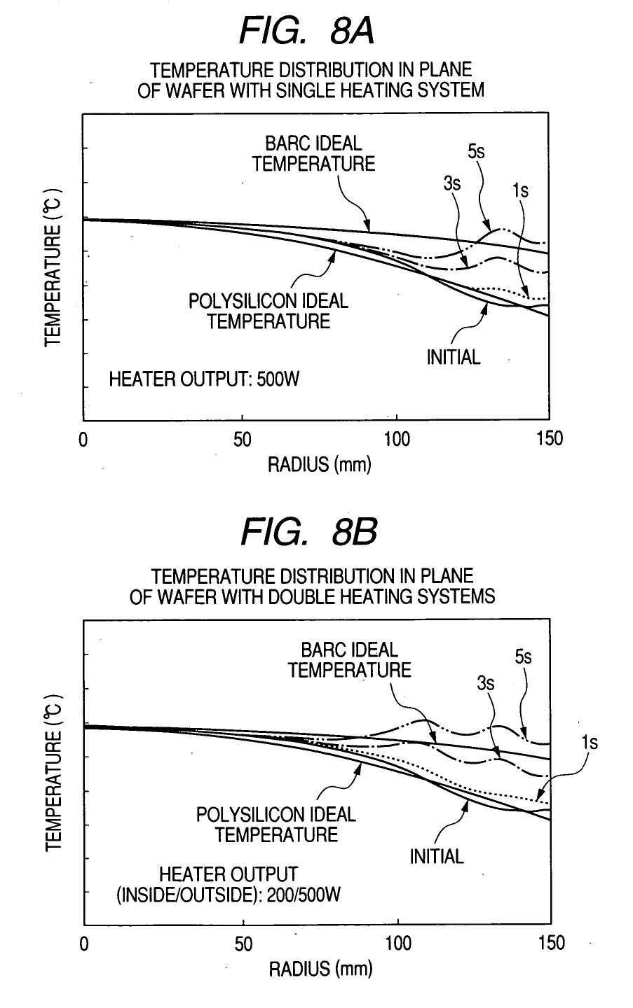

A second embodiment of the present invention will be described hereinbelow with reference to FIGS. 7A and 7B. FIGS. 7A and 7B are views showing an overall configuration of a sample table for being used in the second embodiment shown in FIG. 1. FIG. 7A is a cross sectional view taken along a line A-A of FIG. 7B, and FIG. 7B is an elevational cross sectional view showing the sample table and a related control system. The second embodiment is different from the first embodiment as follows. In the second embodiment, a vacuum insulation layer 29 is provided between the coolant channel 31 and the coolant channel 32 in the base material 2. Further, as shown at 22 and 23, for example, a plurality of heater films are provided. That is, at least heater films 22 and 23, each as a heating system, are disposed on an outer periphery side (outwardly of the vacuum insulation layer 29) and a center side, respectively, with respect to the radial direction of the electrostatic attraction device 8. In the figures, reference character 28A denotes a first heater power source 28B. In the second embodiment, with the vacuum insulation layer 29 provided between the coolant channel 31 and the coolant channel 32, heat transfer between coolants having temperatures different from one another and being circulated to the coolant channel 31 and the coolant channel 32 is reduced, thereby to reduce the thermal load on the circulator that discharges the coolants. In addition, with the plurality of heaters, namely, the heater films 22 and 23, provided in the inner and outer portions, respectively, with respect to the radial direction of the vacuum insulation layer 29, power consumption of the heater films 22 and 23 can be restrained, the response characteristics with respect to temperature variations are improved. Further, the temperature distribution in the plane of the wafer can be finely regulated.

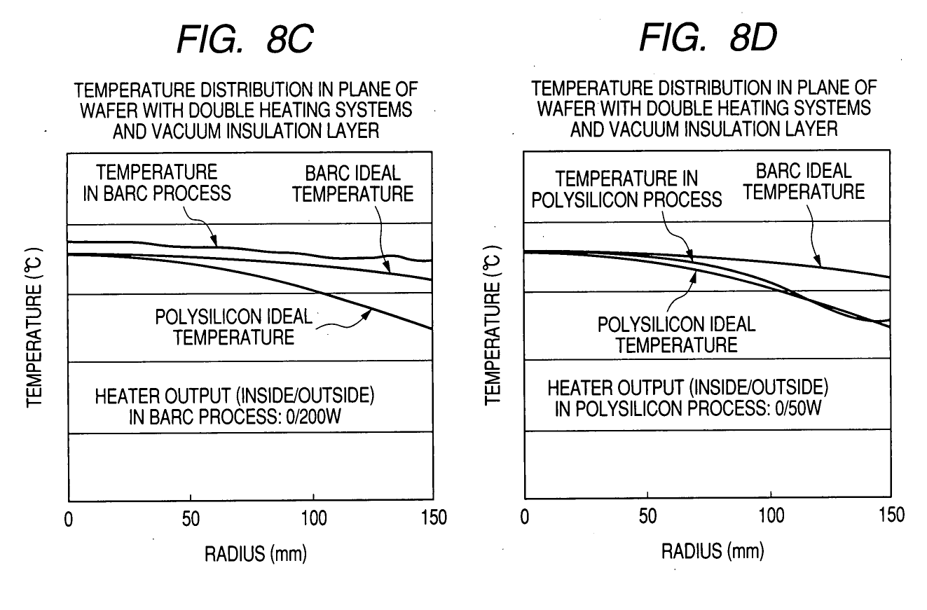

Effects of the present embodiment will be described herein below. FIGS. 8A to 8D each show the temperature distribution in the plane of the wafer in the case where the single heating system is disposed (FIG. 8A), in the case where the double heating systems are disposed (FIG. 8B), and in the case where the double heating systems and the vacuum insulation layer are disposed (FIGS. 8A and 8D). First, temperature regulation of the single heating system and the single heating systems will be described here. The temperatures of the coolant channels 31 and 32 set in coordination with an ideal temperature distribution for performing the process of the polysilicon film, thereby to regulate the temperature distribution so as to be appropriate to process the BARC. In this case, 500 W of power is supplied in the event of performing the process with single heating system, and 200 W and 500 W of power are supplied to the inside and outside heaters, respectively, in the event of performing the process with the double heating systems.

As can be seen from the results shown in FIG. 8A, with the single heating system, a temperature distribution as shown was caused in the range of from 80 mm to 100 mm in the radial direction after five seconds from the heater power-on time with respect to an ideal temperature of BARC. With heater films of the double heating systems being used, as shown in FIG. 8B, a temperature distribution closer to an ideal temperature distribution of the BARC than that in the case of the single heating system was able to be obtained after three seconds from the power-ON time of the heater.

As described above, with the two heating systems (two heaters) being provided, it was verified that the temperature distribution in the plane of the wafer can be finely regulated with good response characteristics. However, since increase in the power supply for the heater should be considered, results in the case where the double heating systems and the vacuum insulation layer are provided will be described. In practice, etching is continuously performed on the BARC and then on the polysilicon film. As such, in the present embodiment, the temperature of the base material 2 is set slightly lower than the ideal temperature of the polysilicon. Then, as shown in FIG. 8C, in the event of the process of the BARC, 0 W and 200 W of power are supplied to the inside and outside heaters, respectively. In a time from the instance of the process of the BARC to the instance of the process of the polysilicon film, in the heater-OFF state, 0 W and 50 W of power were supplied synchronously with the start of the process of the polysilicon film, as shown in FIG. 8D. Consequently, since the vacuum insulation layer is provided, ideal temperature distributions were able to be realized with a small amount of power on both the BARC and polysilicon films.

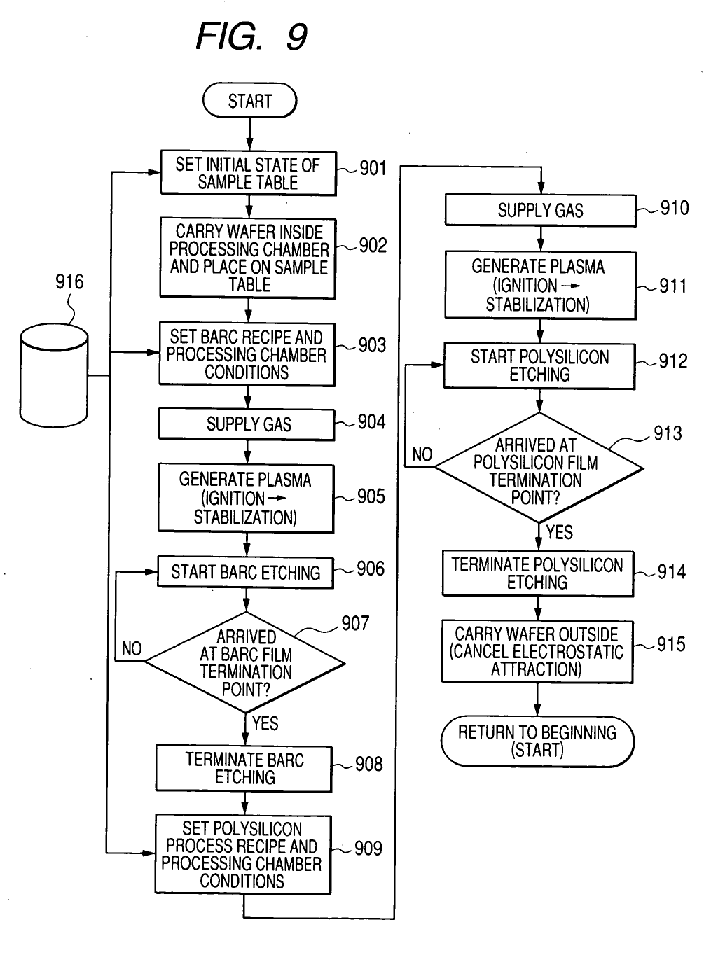

Flow of the process of the wafer 9 in the vacuum processing system according to any one of the above-described embodiments will be described with reference to FIG. 9. FIG. 9 is a flow diagram showing flow of operation of the process of the wafer 9 that is executed by the vacuum processing system according to any one of the embodiments shown FIGS. 1 and 7. More specifically, the flow diagram shows the flow of operation to be performed in a case that a film structure equivalent to that shown in FIG. 6 is disposed on the surface of the wafer 9, and etching process is performed on the film structure. In this case, the film structure has films formed to be a photoresist film, BARC, polysilicon film, oxide film, and silicon substrate layer in the order from the upper side.

With reference to FIG. 9, at the outset, when starting the process of the wafer 9, setting is executed to set an initial state and conditions for the temperature distribution and the like of the electrostatic attraction device 8 (step 901), which is the sample table for mounting the wafer 9. In this case, appropriate setting conditions are read from data contained in a database 916 and received by the controller unit 110 of the vacuum processing system, whereby operation of the vacuum processing system is set. The database 916 is stored in a storage device, such as a hard disk, provided in the vacuum processing system or located in a remote site with which communication can be effected through a communication device or the like. After completion of the setting, the wafer 9 is carried inside the vacuum processing chamber 1 and is mounted on a mounting surface of the silicon substrate layer of the electrostatic attraction device 8 (step 902).

In this state, information, such as a recipe suited for the process of the BARC and conditions such as the temperatures of the coolants in the electrostatic attraction device 8, and helium gas pressure and bias power for the interior of the processing chamber, are read from the data contained in the database 916, and operation of the vacuum processing system is regulated by the controller unit 110 in coordination with the respective conditions (step 903). For example, the heater film 22 is energized with the set amount of power and is heated to provide an appropriate temperature distribution in the wafer 9.

Subsequently, processing gases are supplied into the vacuum processing chamber 1 (step 904). Then, the processing gases are excited by using electric fields and magnetic fields of the microwave oscillator 19, coil 6, and the like shown in FIG. 1, whereby plasma is ignited and stabilized (step 905). Thereby, the etching process of the BARC is started (step 906). Arrival at a termination point of the BARC process is monitored (step 907) by a termination-point determination device (not shown) disposed in the vacuum processing system according to the embodiment shown in FIG. 1. If it is determined that the process has not arrived at the termination point, then the operation returns to step 906. Alternatively, if it is determined that the process has arrived at the termination point, then the process proceeds to step 908, and the etching process is stopped.

Subsequently, information such as a recipe suited for the process of the polysilicon film, which is a lower layer, and operation conditions for the interior of the processing chamber are read from the data contained in the database 916, are received by the controller unit 110, and operation conditions for the vacuum processing system are set to be suitable for the process of the polysilicon film (step 909). In this event, similarly as in the above-described first embodiment, the amount of power to be supplied to the heater film 22 and the like is regulated, and the temperature distribution in the wafer 9 is altered and set. For example, power supply to the heater film 22 is stopped, and the temperature distribution in the electrostatic attraction device 8 or the temperature distribution in the wafer 9 is abruptly altered to the initial state, whereby setting is performed in a short time.

In this state, gases are supplied into the vacuum processing chamber 1 (step 910), plasma is formed (step 911), and the etching process of the polysilicon film is started (step 912). Similarly as in step 907, also in the case of the polysilicon film, arrival at the termination point is monitored by the termination-point determination device (step 913). If it is determined that the process has arrived at the termination point, the process is returned to step 912 and is thereby continued until it is determined that the process has arrived at the termination point. If it is determined that the process has arrived at the termination point of the polysilicon film, at step 914 the etching process is stopped. In this event, cancellation of attraction forces of the electrostatic attraction films 33 and 34 and charge neutralization are effected. Thereby, the wafer 9 is separated from the electrostatic attraction device 8, and is then carried outside the chamber (step 915). After the wafer 9 is thus carried away, in an event that the process of another wafer is performed, then the process returns to the beginning (“START”). In another event, the process enters a standby state.

As described above, in the event of continuously processing a layered structure having a plurality of vertically disposed film layers, regulation is performed for the power being supplied to the heater film disposed in the dielectric film constituting the sample-mounting surface, particularly, to the heater film disposed and surrounded between the electrostatic attraction film. In accordance with the regulation, the temperature distribution can be altered in a short time with high accuracy, and the efficiency in the event of processing a plurality of films can be improved. Consequently, the operating efficiency of the vacuum processing system can be significantly improved.

Although the present invention have been described in detail with reference to the embodiments, it should be understood that various changes, substitutions, and alterations can be made herein without departing from the spirit and scope of the invention as defined by the appended claims.

What is claimed is:

1. A vacuum processing system comprising a vacuum vessel of which an interior is decompressed, a sample table disposed in the vacuum vessel, an electrostatic attraction device that is provided to the sample table and that holds a semiconductor wafer,
wherein
plasma is formed above the sample table to perform an etching process of the semiconductor wafer; and
the electrostatic attraction device includes
a first dielectric film formed on a base material having electro-conductivity;
a plurality of substantially ringular electrode films for electrostatic attraction, the electrode films being coaxially formed on a surface of the first dielectric film to be spaced away from one another;
a ringular heater film formed between the electrode films in a radial direction of the electrode films; and
a second dielectric film formed on upper surfaces of the electrode films and the heater film.

2. A vacuum processing system comprising a vacuum vessel of which an interior is decompressed, a sample table disposed in the vacuum vessel, an electrostatic attraction device that is provided to the sample table and that holds a semiconductor wafer,
wherein
plasma is formed above the sample table to perform an etching process of the semiconductor wafer; and
the electrostatic attraction device includes
a first ceramic film formed by a spray method on a base material having electro-conductivity;
a plurality of electrode films for electrostatic attraction, the electrode films being coaxially formed by a spray method on a surface of the first ceramic film to be spaced away from one another;
a ringular heater film formed in a spray method between the electrode films in a radial direction of the electrode films; and
a second ceramic film formed by a spray method on upper surfaces of the electrode films and the heater film.

3. A vacuum processing system according to claim 2, wherein the electrostatic attraction device includes a plurality of the heater films provided to be spaced away from one another in a radial direction.

4. A vacuum processing system according to claim 3, wherein
the electrostatic attraction device includes a vacuum insulation layer formed in the base material located below the first ceramic film; and
the heater films are provided on an inner side and an outer side in a radial direction of a position corresponding to the vacuum insulation layer.

5. A vacuum processing system comprising a vacuum vessel of which an interior is decompressed, a sample table disposed in the vacuum vessel, an electrostatic attraction device that is provided to the sample table and that holds a semiconductor wafer,
wherein
plasma is formed above the sample table to perform an etching process of the semiconductor wafer;
the electrostatic attraction device includes a first dielectric film formed on a base material having electro-conductivity; a plurality of substantially ringular electrode films for electrostatic attraction, the electrode films being coaxially formed on a surface of the first dielectric film to be spaced away from one another; a ringular heater film formed between the electrode films in a radial direction of the electrode films; and a second dielectric film formed on upper surfaces of the electrode films and the heater film; and
the vacuum processing system comprises
a heater power source for supplying power to the heater film; and
a controller for controlling the power to be supplied.

6. A vacuum processing system according to claim 5, wherein a temperature distribution in a plane of the semiconductor wafers is controlled by control of the heater film.
